(19) United States
(12) Patent Application Publication
(10) Pub. No.: US 2025/0028008 A1
(43) Pub. Date: Jan. 23, 2025

(54) DEVICE, SYSTEM AND METHOD FOR PERFORMING A CONTINUITY TEST OF AN ELECTRICAL LINE OF AN OBJECT

(71) Applicant: TOP seven GmbH & Co. KG, Munchen (DE)

(72) Inventor: Ulrich Seng, Starnberg (DE)

(21) Appl. No.: 18/907,079

(22) Filed: Oct. 4, 2024

Related U.S. Application Data
(63) Continuation of application No. PCT/EP2023/058876, filed on Apr. 4, 2023.

(30) Foreign Application Priority Data
Apr. 6, 2022 (DE) 102022203443.0

(51) Int. Cl. G01R 31/54; F03D 17/00; G01R 31/371

(52) U.S. Cl. CPC G01R 31/54; F03D 17/009; F03D 17/028; G01R 31/371; F05B 2260/83

(57) ABSTRACT

Embodiments according to the present invention include a device for providing an electrical test signal, for performing a continuity test of an electrical line of an object, including: a communication module configured to receive an activation signal for switching the device from a passive operating mode to an active operating mode, and to obtain a deactivation signal for switching the device from the active operating mode to the passive operating mode. Furthermore, the device includes a signal generator configured to generate the electrical test signal in the active operating mode. In addition, the device includes an energy source configured to supply the communication module and the signal generator with energy. The device also includes a coupling-in module configured to couple the electrical test signal into the electrical line of the object in the active operating mode.

### CROSS-REFERENCES TO RELATED APPLICATIONS

This application is a continuation of copending International Application No. PCT/EP2023/058876, filed Apr. 4, 2023, which is incorporated herein by reference in its entirety, and additionally claims priority from German Application No. DE 10 2022 203 443.0, filed Apr. 6, 2022, which is incorporated herein by reference in its entirety.

Embodiments according to the present invention concern devices, systems, and methods for performing a continuity test of an electrical line of an object.

### BACKGROUND OF THE INVENTION

Wind turbines already form an integral part of renewable energy sources in many countries. To ensure the safe and reliable operation of such wind turbines, it is therefore important to inspect them at regular intervals. Due to their design, e.g. due to ever-increasing tower heights and rotor blade lengths, wind turbines are at particular a risk from lightning strikes. In order to be able to conduct away the energy of lightning in the event of a lightning strike and to prevent damage to a wind turbine, wind turbine rotor blades are fitted with lightning rods (or lightning conductors). However, these lightning rods may become damaged or unusable, e.g. due to mechanical stress during wind turbine operation or environmental influences such as oxidation. The lightning rods are usually arranged inside the rotor blades so that inspection is not easily possible. Therefore, their inspection is usually associated with high costs and a great deal of effort.

Therefore, there is a need for a concept that enables continuity testing of an electrical line of an object, such as a wind turbine, with low complexity and with little effort and thus at low costs.

### SUMMARY

An embodiment may have a device for providing an electrical test signal, for performing a continuity test of an electrical line of an object, comprising: a communication module configured to: acquire an activation signal to switch the device from a passive operating mode to an active operating mode, and acquire a deactivation signal to switch the device from the active operating mode to the passive operating mode; and a signal generator configured to generate the electrical test signal in the active operating mode; an energy source configured to supply the communication module and the signal generator with energy, and a coupling-in module configured to: couple the electrical test signal into the electrical line of the object in the active operating mode.

Another embodiment may have a system for providing electrical test signals, for performing a continuity test of electrical lines of an object, wherein the object is a wind turbine with a plurality of rotor blades, the rotor blades each comprising electrical lines in the form of lightning rods, and wherein the system further comprises: a plurality of devices according to the invention, wherein a respective coupling-in module of a respective device is configured to couple a respective electrical test signal into a respective rotor blade for continuity testing of a respective lightning rod.

Another embodiment may have a system for providing an electrical test signal, for performing a continuity test of an electrical line of an object, comprising: a device according to the invention; a communication unit configured to: transmit the activation signal and the deactivation signal to the communication module of the device; and a measuring unit configured to detect the test signal.

Another embodiment may have a method of performing a continuity test of an electrical line of an object, comprising: supplying a communication module with energy of an energy source; and acquiring an activation signal by means of the communication module to switch from a passive operating mode to an active operating mode; and supplying a signal generator with energy of the energy source in the active operating mode; and generating an electrical test signal by means of the signal generator in the active operating mode; and coupling the electrical test signal into the electrical line of the object in the active operating mode; and acquiring a deactivation signal by means of the communication module to switch from active operating mode to passive operating mode.

Embodiments according to the present invention include a device for providing an electrical test signal, for performing a continuity test of an electrical line (also referred to herein as an electrical conductor) of an object, including a communication module configured to obtain an activation signal to set the device from a passive operating mode to an active operating mode, and to obtain a deactivation signal to set the device from the active operating mode to the passive operating mode. Furthermore, the device includes a signal generator configured to generate the electrical test signal in the active operating mode. Furthermore, the device includes an energy source configured to supply the communication module and the signal generator with energy. In addition, the device includes a coupling-in module configured to couple the electrical test signal into the electrical line of the object in the active operating mode.

Embodiments according to the present invention are based on the core idea of coupling-in a test signal into the electrical line of the object to be tested in order to subsequently detect the test signal, e.g. non-invasively, with a measuring device in order to draw conclusions about a state of the line of the object. For this purpose, the device includes the signal generator configured to provide the test signal for the coupling-in module. The inventors have realized that the use of the communication module makes it possible to control the device remotely, so that the testing effort may be reduced, especially in the case of very large objects. For example, in the case of a wind turbine, it may not be necessary for a system tester to climb the tower of the wind turbine to the feed-in point of the electrical test signal in order to activate the device, or in other words, to put it into an active operating mode. This may allow a device according to the invention to be firmly connected to the object in order to activate the device only in the course of an inspection and then deactivate it again.

Further embodiments according to the present invention include a method for performing a continuity test of an electrical line of an object, comprising supplying a communication module with energy from an energy source and obtaining an activation signal by means of the communication module to switch to an active operating mode from a passive operating mode. Furthermore, the method includes supplying a signal generator in the active operating mode with energy from the energy source and generating an electrical test signal in the active operating mode by means of the signal generator. In addition, the method includes coupling the electrical test signal into the electrical line of the object in the active operating mode and obtaining a deactivation signal by means of the communication module to switch from the active operating mode to the passive operating mode.

The method described above is based on the same considerations as the device described above. The device may accordingly be supplemented with all the features and functionalities described in connection with the method, both individually and in combination.

According to further embodiments of the present invention, the communication module is configured to obtain the activation signal and/or the deactivation signal in a wireless manner. The inventors have realized that wireless communication of the communication module allows a high degree of flexibility in providing the electrical test signal. In particular for very large objects, a location where the test signal is fed into the line of the object may be far away from a location where the test signal needs to be detected. Thus, e.g., particularly in the case of objects that are difficult to access, such as a wind turbine, the device may be set to the active operating mode from various positions on the object in order to couple the test signal into the line. For example, a climber having a portable measuring device alone on the rotor blade may activate the test signal in order to detect the electrical test signal in the lightning rod of the rotor blade. This means, e.g., that no second person is required to control the device and coordinate with the climber. Furthermore, wireless communication also enables the use of automated testing methods. For example, a drone flying over the object may use wireless communication to activate the device in order to couple the test signal into the line of the object to subsequently measure the electrical test signal and to deactivate the device again using wireless communication once the measurement or inspection is complete. The communication module may be a radio module, for example.

According to further embodiments of the present invention, the communication module is configured to obtain the activation signal or the deactivation signal in a wired manner. For example, in a case where the device is fixedly attached to the object, the object may have a wired communication line to the device so that, e.g., a connection possibility may be provided from an easily accessible location on or in the object to control the device. For example, in the case of an autonomous drone (optionally also in the case of a manually controlled drone or a semi-autonomous drone) configured to inspect the object and measure the test signal in the electrical line, the drone may thus be controlled or started at the base of the system with a computing unit and at the same time the device may be set to the active operating mode by means of a connection on the object. Furthermore, wired communication may be more resistant to interference than, e.g., wireless communication. Furthermore, according to an embodiment, the device may be configured in a wired manner, e.g. via a USB connection.

According to further embodiments of the present invention, the energy source comprises at least one of a replaceable energy storage and/or a rechargeable energy storage.

Alternatively or additionally, the energy source is configured to be coupled to an external power supply. The inventors have realized that by using an energy storage, the device may be operated or used at least approximately or temporarily self-sufficiently. For example, the device may be structurally connected to the object in order to be activated by means of the communication module for performing the continuity test during an inspection. Accordingly, it is not necessary for the device to be supplied with energy beforehand, e.g. by manually connecting a cable to the device. In the case of a wind turbine, e.g., the device may be installed near the rotor blade base, e.g. in the nacelle, and activated by means of a drone via wireless communication, wherein both the communication and the generation of the test signal may be enabled based on energy provided by a replaceable or rechargeable energy storage. Using appropriately dimensioned energy storages, the energy storage may be replaced or recharged at regular intervals in the course of further routine inspections (e.g. at longer time intervals than time intervals between continuity tests), e.g. of the corresponding nacelle. This may optimize and save effort and time. It is to be noted that these advantages are not only relevant for wind turbines, but in particular for any large object where a corresponding device for continuity testing of a conductor has to be installed in a location that is difficult to access, for example.

Furthermore, however, the inventors have also realized that, e.g., in the case of objects used to generate energy or supplied with energy, e.g. constantly, the energy source may also be configured to be coupled to an external power supply, e.g. a power supply of the object. This may also provide an efficient method of power supply for the device in order to be able to use the device for continuity testing over long periods of time and with additional effort.

According to further embodiments of the present invention, the coupling-in module is configured to inductively couple the electrical test signal into the electrical line of the object in the active operating mode. Alternatively or additionally, the coupling-in module is configured to capacitively couple the electrical test signal into the electrical line of the object in the active operating mode. The inventors have realized that inductive or capacitive coupling of the test signal enables particularly advantageous line testing. On the one hand, objects may be retrofitted by means of the device without, e.g., having to make direct electrical contact with conductors that are difficult to access and need to be tested. On the other hand, such coupling-in may also have particular advantages with regard to objects with moving electrical cables, where a corresponding continuity test is only possible in certain positions or orientations of the electrical cable, e.g., wherein it may be advantageous for the cable to be able to move relative to the continuity test device during regular operation of the object.

According to further embodiments of the present invention, the coupling-in module is configured to be attached to the electrical line in an electrically isolated manner such that the device is substantially protected from a voltage and/or current spike on the electrical line. Very large objects in particular may be susceptible to lightning strikes, which can lead to high voltages and/or currents on electrical lines within the object. Coupling the device by means of the coupling-in module to the line with appropriate galvanic isolation may prevent damage to or destruction of the device, e.g. in the event of such a lightning strike.

According to further embodiments of the present invention, the coupling-in module comprises an electrically switchable ohmic connection to the line of the object for coupling the electrical test signal into the electrical conductor of the object in the active operating mode. The inventors have realized that in some cases, e.g. when the device is structurally connected to the object, the test signal may also be coupled-in into the object or the conductor of the object via a switchable ohmic connection. For example, this may provide for a particularly interference-resistant and direct test signal coupling, e.g. for very strong electrical test signals, such as those having high voltages or high currents. The use of a switchable ohmic connection may ensure appropriate decoupling, e.g. to protect against lightning strikes. For example, test signals including low-frequency signals or clocked low-frequency signals may also be used for ohmic coupling-in.

According to further embodiments of the present invention, the device is configured to reduce energy consumption of the device in the passive operating mode compared to the active operating mode, and to activate the communication module in the passive operating mode at time intervals for a predetermined duration to obtain the activation signal. The inventors have realized that by means of such a passive operating mode, energy may be saved in periods in which no inspection, e.g. a continuity test of a line of the object, is necessary or planned. Accordingly, with regard to replaceable or rechargeable energy storages, e.g., a period until replacement or recharging is necessary may be extended. Furthermore, the inventors have realized that by cyclically activating the communication module to obtain the activation signal, the device may be set to the active operating mode for inspection with little effort. This means, e.g., that it is not necessary for a person to manually activate the device in order to start an inspection.

According to further embodiments of the present invention, the energy source comprises at least one of a replaceable energy storage and/or a rechargeable energy storage, and the communication module is configured to transmit a charge state of the energy storage in the active operating mode. The inventors have realized that this may improve the reliability of the device. Accordingly, the charge state of the energy storage may be monitored during an inspection in order to obtain information on whether the inspection may be carried out with the remaining energy supply, e.g. to determine an ageing state of the energy storage, e.g. via an energy delta since the last inspection with transmission of the previous charge state, and/or to plan a replacement or recharging of the energy storage.

According to further embodiments of the present invention, the communication module is configured to transmit information about the operating state of the device. Thus, e.g., the device may, after obtaining an activation signal, report back that the device has obtained the activation signal by transmitting information about the active operating state. For example, this may ensure that the device is ready to generate the test signal before a complex measurement is prepared on the line of the object.

According to further embodiments of the present invention, the electrical test signal is a high-frequency signal, a radio-frequency signal, a low-frequency signal and/or a clocked low-frequency signal. The inventors have realized that a high-frequency signal, e.g., enables efficient continuity testing of an electrical line of an object in many cases. Thus, e.g., a radiated electrical or electromagnetic field of the high-frequency signal in the electrical line may also be detected from a certain distance from the electrical line.

For example, in a rotor blade of a wind turbine, there may be several connections (e.g. screw connections) in the course of the down conductor (e.g. lightning conductor or lightning rod). Metal surfaces meet at these points and form contact connections between conductors that occasionally carry current. In the presence of oxygen or other gases having chemically aggressive effects, the surface of base metals reacts: layers of oxides, sulphides, chlorides and similar substances may form. Furthermore, a water film may form under standard atmospheric conditions.

Finally, contamination with oil, grease and dust that cannot be prevented with respect to the structure has to also be taken into account. These changes or impairments can lead to foreign layers on the material, which may significantly disturb the current transfer or interrupt it completely.

The inventors have realized that the use of a high-frequency signal enables a sophisticated evaluation in order to differentiate between areas that are problematic for a lightning strike and areas of a lightning rod (or lightning conductor) that are only slightly oxidized or interrupted.

For example, to test the continuity of the down conductors in the rotor blades, the inventive testing method may use an electrically induced field capable of bridging the described tarnished and foreign layers by induction.

According to further embodiments of the present invention, the signal generator is configured to enable impedance matching with respect to the electrical line. The inventors have realized that this may enable particularly efficient coupling-in into the electrical line. Furthermore, the signal generator may be configured to perform a calibration, e.g. for different electrical lines of different objects, in order to perform a corresponding impedance matching as efficiently as possible.

Specifically, the generator output of the signal generator within the device may, e.g., perform impedance matching (radiation) within certain limits, i.e. an optimized value may be set at least approximately depending on the system, e.g. the conductor of the object.

According to further embodiments of the present invention, the device comprises at least one protective diode and the protective diode is configured to protect the device from a voltage and/or current spike on the electrical line. For example, the protective diode may be configured to conduct away an overvoltage or an overcurrent, or to dissipate a corresponding overcurrent or a corresponding overvoltage. For example, this may enable lightning strikes or strong electrical feedback, e.g. at objects configured to generate large amounts of energy.

For example, the protective diode may be a bipolar transil diode (or transient-voltage-suppression diode). The diode does not need conduction down to earth, e.g., but may be mounted internally in parallel with the coupling-in module, e.g. the induction coil, and thus intercept overvoltage pulses, e.g. in the event of a lightning strike. For example, the coupling-in module may be bypassed by means of the protective diode.

For example, this protection against lightning strikes may only be possible with inventive solutions (e.g. having inductive coupling with galvanic isolation, e.g. in the case of an induction coil-no ohmic connection).

For example, this offers advantages over an ohmic signal feed (e.g. by interrupting the line and feed-in on both sides), as the risk of destruction or lightning protection may no longer be guaranteed in the event of a lightning strike.

The protective diode may generally be a transient voltage-suppression (TVS) diode, e.g. a suppressor diode, e.g. a transistor diode or a thyrector. For example, the protective diode may therefore be an electrical component by means of which electrical circuits, e.g. the device according to the invention, e.g. in particular the signal generator and the communication module and corresponding lines of the device, may be protected from voltage peaks induced in lines.

For example, such a protective diode may shunt an overcurrent (for example, the current of the pulse may be conducted past the component to be protected, e.g. based on a parallel circuit) if an induced voltage exceeds, e.g., a breakdown voltage, e.g. an avalanche breakdown voltage. For example, the protective diode may be a clamping circuit (clamping device) and may be configured to suppress overvoltages above a breakdown voltage.

For example, the protective diode may automatically reset itself when the overvoltage is no longer present and may, e.g., absorb a lot of transient energy internally, e.g. more than a similarly classified clamping circuit (crowbar device). The protective diode may be configured uni- or bidirectionally.

A unidirectional diode may act as a forward rectifier, like an avalanche diode, but may be configured and tested to handle very large current peaks.

Bidirectional TVS diodes may be represented by two mutually opposing avalanche diodes connected in series with each other and in parallel with the component to be protected. However, e.g., this type of representation may only be schematically correct, physically, such devices may be manufactured as individual components.

According to further embodiments of the present invention, the protective diode is a suppressor diode and the suppressor diode is connected in parallel with the coupling-in module. For example, the suppressor diode may be a bipolar transistor diode. For example, such a diode does not need down conduction towards ground, but may be mounted internally in the device in parallel with the coupling-in module, e.g. an induction coil, and may thus dissipate overvoltage pulses, e.g. in the event of a possible lightning strike.

According to further embodiments of the present invention, the test signal may comprise a modulated signal identifier. The inventors have realized that this may improve the robustness of the continuity test, e.g. by using the modulated identifier to distinguish the test signal from other signals or interference signals during detection of the test signal.

According to further embodiments of the present invention, the object is a wind turbine with a plurality of rotor blades, wherein the rotor blades each have electrical lines in the form of lightning rods (or lightning conductors). Furthermore, the electrical line is a lightning rod of a rotor blade of the wind turbine. As previously explained, the inventive device has great advantages in particular with regard to a continuity test of a lightning rod of a rotor blade of a wind turbine.

For example, such an inspection may be carried out by a single person who activates the device in a wired or wireless manner from the ground in order to couple a test signal into a lightning rod of a rotor blade. For example, a drone may then fly over the rotor blade and record the test signal. This may indicate the condition of the lightning rod. The device may then be deactivated again accordingly. This may provide a continuity test with little personnel and time expenditure.

For example, the device may be arranged in the hub, in the flange, or in a rotor blade of the wind turbine. For example, the test signal may be efficiently coupled-in into the lightning rod of the rotor blade at an attachment (or a base) of the rotor blade.

Alternatively, e.g., when flying across the wind turbine, the drone may provide the activation signal for the device. For example, it may no longer be necessary for several service technicians to climb into the hub of the blade attachment to activate a corresponding device, e.g. for safety reasons or legal requirements. Furthermore, the corresponding device may also be permanently attached to the wind turbine so that a corresponding device does not even have to be attached separately for the inspection. For example, the coupling-in module may be a pair of pliers, e.g. induction pliers, or a ring, e.g. an induction ring, attached to a corresponding lightning protection cable or permanently attached to the structure.

According to further embodiments of the present invention, the coupling-in module is configured to be attached to the lightning rod of a rotor blade and/or to be integrated into the lightning rod of the rotor blade. Alternatively or additionally, the coupling-in module is configured to be attached in a supply line to the rotor blade and/or to be integrated in the supply line and/or to be integrated in a rotor blade and/or to be attached in a rotor blade. Embodiments of the present invention are not limited to a special attachment of the coupling-in module to the lightning rod. Depending on the design of the wind turbine or, e.g., whether the device for the wind turbine is retrofitted or is already provided directly during the production of the wind turbine, a corresponding coupling-in module may be used with a high degree of flexibility.

According to further embodiments of the present invention, the device has a plurality of coupling-in modules corresponding to the plurality of rotor blades, wherein a respective coupling-in module is configured to couple the electrical test signal for continuity testing of a respective lightning rod into a respective rotor blade. This means that a large number of lightning rods on the rotor blades of a wind turbine may be tested with a single device. For example, the test signal may be coupled into the various lightning rods one after the other so that, e.g., a single drone sequentially flies over a corresponding rotor blade having a coupled test signal in order to detect the test signal. Alternatively, however, the test signal may also be coupled into the plurality of rotor blades simultaneously, e.g. in order to check the lightning rods of the rotor blades in a particularly time-efficient manner, e.g. with a plurality of drones at the same time. For example, the coupling-in modules may be fed by the one signal generator.

According to further embodiments of the present invention, the device has a plurality of coupling-in modules corresponding to the plurality of rotor blades, wherein a respective coupling-in module is configured to couple a respective electrical test signal for continuity testing of a respective lightning rod into a respective rotor blade. Furthermore, the device has a plurality of signal generators corresponding to the plurality of coupling-in modules, wherein a respective signal generator of the plurality of signal generators is configured to generate the respective electrical test signal for coupling-in into a respective lightning rod in the active operating mode. In simple terms, each coupling-in module of the device may have an associated signal generator, e.g. to conduct respective electrical test signals simultaneously or successively into respective lightning rods of the rotor blades. Thus, e.g., the device may be more modularized so that the device may include an individual coupling-in and signal generator module for each rotor blade.

According to further embodiments of the present invention, the energy source is configured to supply the plurality of signal generators with energy. Alternatively, the device has a plurality of energy sources corresponding to the plurality of signal generators and a respective energy source of the plurality of energy sources is configured to supply a respective signal generator of the plurality of signal generators with energy. Thus, e.g., a single central energy source may be provided for the energy supply, e.g., which can then be replaced with particularly little effort. Alternatively, the device may be more modularized so that a coupling-in module, a signal generator and an associated energy source may be provided for each rotor blade, for example. Furthermore, there may also be another additional energy source to supply the communication module. Depending on the specific application, the device may therefore be designed to be particularly fail-safe, e.g. by being more modular so that individual modules can be easily replaced or have fewer components, e.g. with a centralized signal generator and/or a centralized energy source.

Further embodiments according to the present invention include a system for providing electrical test signals, for performing continuity testing of electrical lines of an object, wherein the object is a wind turbine with a plurality of rotor blades, wherein the rotor blades each have electrical lines in the form of lightning rods, and wherein the system further includes a plurality of devices, according to one or more of the embodiments disclosed herein, wherein a respective coupling-in module of a respective device is configured to couple a respective electrical test signal for continuity testing of a respective lightning rod into a respective rotor blade. Put simply, a device according to the inventive design may therefore be provided for each rotor blade, e.g., in order to couple a corresponding test signal. For example, the devices may each be controlled with different activation and deactivation signals in order to activate or deactivate the devices iteratively one after the other, e.g., in order to test a respective lightning rod of a respective rotor blade. Furthermore, however, the devices may also respond to a common activation and/or deactivation signal so that, e.g., a plurality of test signals are provided simultaneously in the rotor blades. In such a case, e.g., identifiers that are modulated onto a respective test signal may be different in order to be able to distinguish the signals.

Further embodiments according to the present invention include a system for providing an electrical test signal, for performing continuity testing of an electrical line of an object, comprising a device according to one or more of the embodiments disclosed herein, a communication unit configured to transmit the activation signal and the deactivation signal to the communication module of the device, and a measuring unit configured to detect the test signal. For example, the communication unit may be a laptop or a unit that can be attached to a drone. For example, in the case of a laptop, an activation signal may be provided via a port in the object being connected to the communication module of the device. For example, during an inspection flight of a drone, the activation signal may be transmitted in a wireless manner to a communication module of the device by means of a communication unit attached to the drone. For example, the measuring unit may be a handheld device used by technicians or climbers, e.g., to detect the inspection signal in the vicinity of the line of the object. However, e.g., the measuring unit may also be configured to be attached to a drone so that the test signal may be detected when the object flies off. For example, this may achieve a high degree of automation of the inspection of the line of the object.

According to an embodiment of the present invention, the communication unit is configured to be attached to a drone. As already explained above, the device may thus be activated during a manual, automatic, autonomous, or semi-autonomous (e.g. with a correction of a, e.g. predetermined, flight direction or distance (e.g. from the object) e.g. via an additional measuring system, e.g. lidar) flight of the drone along the object, e.g. in the course of a regular inspection, and may also be deactivated again, e.g. after completion of the passage inspection. For example, the drone may be controlled or launched from the ground so that it is not necessary for people to go to high altitudes or to places that are difficult to access to carry out an inspection, in particular a continuity test, especially in the case of large objects.

According to further embodiments of the present invention, the measuring unit is configured to be attached to a drone and to detect the test signal during an inspection flight of the drone along the object. As explained above, this may also save human personnel during measurement and reduce the risk to human personnel. The drone may also reach into areas that are inaccessible or difficult to reach for humans in order to detect the test signal and determine the condition of the object or the line of the object.

According to further embodiments of the present invention, the object is a wind turbine with a plurality of rotor blades, wherein the rotor blades each have electrical conductors in the form of lightning rods, and wherein the system further includes a plurality of devices according to one or more of the embodiments disclosed herein, wherein a respective coupling-in module of a respective device is configured to couple a respective electrical test signal for continuity testing of a respective lightning rod into a respective rotor blade. Furthermore, the communication unit is configured to transmit the activation signal and the deactivation signal to a respective communication module of a respective device. Furthermore, a drone has the measuring unit and the drone is configured to fly to the wind turbine and to fly over the plurality of rotor blades.

In particular, the drone may be configured to autonomously approach the wind turbine and autonomously fly over the plurality of rotor blades. In particular, the measuring unit may be configured to detect the test signal during autonomous flight of the rotor blades. The inventors have realized that this may provide a simple and efficient automated system for testing lightning rods of wind turbines. By providing an inventive device for a respective lightning rod or a respective rotor blade, the system is particularly robust and also enables simultaneous testing of the plurality of rotor blades, e.g. using a corresponding plurality of drones having a corresponding number of measuring units. It should again be noted that the drone may also be controlled manually, automatically, or semi-autonomously.

It is to be noted once again that the measuring unit may also be a portable device. Accordingly, embodiments are not limited to the use of drones. For example, however, an inspection may also be carried out with a drone, e.g. to determine an approximate area of damage to the lightning protection line, where climbers with portable measuring units then scan the wind turbine or, more precisely, the rotor blades again in order to find and repair a corresponding damaged area.

According to further embodiments of the present invention, a method according to the inventive further includes transmitting the activation signal to the communication module by means of a communication unit, scanning the object with a measuring unit, detecting the test signal when scanning the object, and transmitting the deactivation signal to the communication module by means of the communication unit.

For example, general information about damage to a lightning rod of a rotor blade may be known. To repair it, a climber may then climb the rotor blade and transmit the activation signal to the communication module of the device, e.g. in a wireless manner using a portable communication unit. Then the climber may climb down the rotor blade and the test signal may be detected by the climber, e.g., with a portable measuring unit. In this way, the damaged area may be determined very precisely, e.g. by scanning at a very close distance, and it may be repaired accordingly. At the end of the detection or repair, the deactivation signal may in turn be transmitted to the communication module of the device in order to relieve the load on an energy storage unit of the device, e.g. which may be replaceable, and to enable a long service life.

According to further embodiments of the present invention, an inventive method further includes flying to the object with a drone, the drone having a measuring unit, transmitting the activation signal to the communication module by means of a communication unit, flying along the object by means of the drone, detecting the test signal when flying along the object by means of the measuring unit and transmitting the deactivation signal to the communication module by means of the communication unit. For example, in order to provide information for a subsequent repair, the drone may fly over the object manually, automatically, semi-autonomously, or autonomously using the drone. For example, the transmission of the activation signal may be transmitted when approaching the object, e.g. when a rotor hub is first approached by the drone, e.g., wherein the drone may have the communication unit. Furthermore, however, the communication unit may also be a laptop on the ground of the wind turbine, also used to control the drone, for example. As mentioned above, the activation signal may then also be transmitted by wire via a fixed line in the object, for example. As mentioned above, the approach and take-off of the object may be automated, semi-autonomous, or autonomous, so that an inspection result can be provided with little time and personnel effort (it is to be noted again that a manual flight is also possible). The drone may also fly over the rotor blade or the object's conductor in general at a very short distance in order to detect the inspection signal and then transmit the deactivation signal to the communication module by means of the communication unit after the inspection signal has been detected. This may in turn save energy after the inspection has been completed.

According to further embodiments of the present invention, an inventive method further includes activating the communication module in the passive operating mode at time intervals for a predetermined duration for obtaining the activation signal, transmitting the activation signal by means of the communication unit to the communication module during a time span greater than a time interval between two activations of the communication module, obtaining the activation signal by means of the communication module to switch to the active operating mode from the passive operating mode, and transmitting information about the operating state to the communication unit by means of the communication module.

According to further embodiments of the present invention, at least one of a time information, an absolute position information of the drone, and/or a distance information and/or a position information of the drone with respect to the rotor blade is stored for each detected value of the test signal together with the detected value of the test signal. The inventors have realized that this may enable precise localization of a damaged area.

According to further embodiments of the present invention, an inventive method further includes comparing the detected test signal with a reference signal, wherein the reference signal is a calculated waveform of a detected test signal over the electrical line and/or a waveform of the detected test signal over the electrical line measured during a previous measurement to determine information about damage to the electrical line.

For example, the calculated signal waveform may be the result of a simulation, e.g. based on CAD data. This means that it may also be possible to check whether the conductor or cable is intact and/or has been installed correctly during a first flight on a newly installed system. Furthermore, however, the inventors have also recognized that, e.g., due to different environmental influences and local conditions at the location of the object, the cable or conductor in the object may change in different ways so that a previous measurement result can be used to assess the condition or change in condition.

According to further embodiments of the present invention, in a method according to the invention, the object is a wind turbine having a rotor hub and a plurality of rotor blades arranged on the rotor hub, the rotor blades each having electrical lines in the form of lightning rods (or lightning conductors). Furthermore, devices of a plurality of devices according to one or more of the embodiments disclosed herein are each coupled to a lightning rod of a respective rotor blade. The inventive method further includes approaching the wind turbine, e.g. the rotor hub or a rotor blade tip, by means of a drone, wherein the devices are each in the passive operating mode when the drone approaches. Furthermore, the method includes transmitting an activation signal by means of a communication unit of the drone to a communication module of one of the devices in order to set the one device to the active operating mode. Furthermore, the method includes coupling-in a test signal generated by the signal generator of the one device into the lightning rod of the rotor blade coupled to the one device, by means of the coupling-in module of the one device. In addition, the method of flying along the rotor blade coupled to the one device with the drone while the test signal is coupled-in into the lightning rod of the rotor blade includes detecting the test signal by means of a measuring unit of the drone during the flight along the rotor blade. Optionally, e.g., the method may include flying along the rotor hub or the rotor blade tip again.

Furthermore, the method includes transmitting a deactivation signal to the communication module of the one device by means of the communication unit of the drone in order to place the one device back into the passive operating mode. Furthermore, the method includes iteratively repeating the steps of transmitting an activation signal, coupling-in a test signal, flying along the rotor blade, detecting the test signal, (optionally flying to the rotor hub or the rotor blade tip again), and transmitting a deactivation signal for the further devices and the further rotor blades of the plurality of devices coupled with the devices.

In simple terms, the drone may fly to the wind turbine, e.g. the blade hub or a rotor blade tip. The drone flight may be manual, automated, semi-autonomous, or autonomous, for example. The drone may then initiate a radio signal to place one of the devices into active the operating mode or, simply put, to wake it up. For example, the drone may wait for a certain time span, such as 75 seconds, and provide the activation signal to ensure that a wake-up interval of the communication module is reached in the passive operating mode of the one device or is caught, so to speak, to transmit the activation signal and activate the device. Optionally, feedback from the device about the active operating mode may additionally be transmitted back to the communication unit of the drone by means of the communication module after the device has been activated. The drone may then fly along the wing or rotor blade, e.g. manually, automatically, semi-autonomously, or autonomously, detect the test signal, optionally return to the hub and then return the device to passive operating mode, e.g. a sleep mode. This process may be repeated iteratively, e.g. successively, with the one drone in order to activate the other devices and inspect the other rotor blades.

It is to be noted that embodiments according to the present invention are not limited with respect to a specific flight routing.

Thus, a device according to the invention may be activated by a communication unit of a drone from the hub as mentioned above, but activation may also occur during an approach of the drone to the hub, or an approach of the drone to a rotor blade tip or from a rotor blade tip.

Accordingly, detection of the test signal may also be carried out from a large number of possible starting points and with a large number of possible end points of the flight trajectory. For example, flight to a rotor blade may be take place from a rotor blade tip in order to detect the test signal. Conversely, a test flight may also be started from the hub or the rotor blade flange.

For example, starting from the hub of the wind turbine, a device may be activated to induce the test signal and flight along the associated rotor blade may then take place. Starting from the rotor blade tip, e.g., the device may be switched off again using the deactivation signal, and, e.g., the drone may fly to another rotor blade tip in a waiting mode. On the way to the other tip, e.g., a device associated with the rotor blade may be activated in order to record the test signal in the lightning rod of the rotor blade during this test flight, starting from the rotor blade tip towards the hub.

Accordingly, it is to be noted that embodiments according to the present invention include a plurality of flight routes or flight patterns and, accordingly, procedures for activating and deactivating devices according to the invention.

### BRIEF DESCRIPTION OF THE DRAWINGS

Embodiments of the present invention will be detailed subsequently referring to the appended drawings, in which:

FIG. 1 shows a schematic view of a device for providing an electrical test signal according to embodiments of the present invention;

FIG. 2 shows a schematic view of a device having an optional protective diode according to embodiments of the present invention;

FIG. 3 shows a schematic side view of a wind turbine with an inventive device according to embodiments of the present invention;

FIG. 3a shows a schematic side view of a wind turbine with inventive devices according to embodiments of the present invention;

FIG. 4 shows a system for providing electrical test signals according to embodiments of the present invention;

FIG. 5 shows a further system for providing an electrical test signal having further optional features according to embodiments of the present invention;

FIG. 6 shows a schematic block diagram of electronics of a device according to embodiments of the present invention; and

FIG. 7 shows a schematic block diagram of a method according to embodiments of the present invention.

### DETAILED DESCRIPTION OF THE INVENTION

Before embodiments of the present invention are explained in more detail below with reference to the drawings, it is to be noted that identical, functionally identical or similarly acting elements, objects and/or structures are provided with the same or similar reference numerals in the different figures so that the description of these elements shown in different embodiments is interchangeable or may be applied to one another.

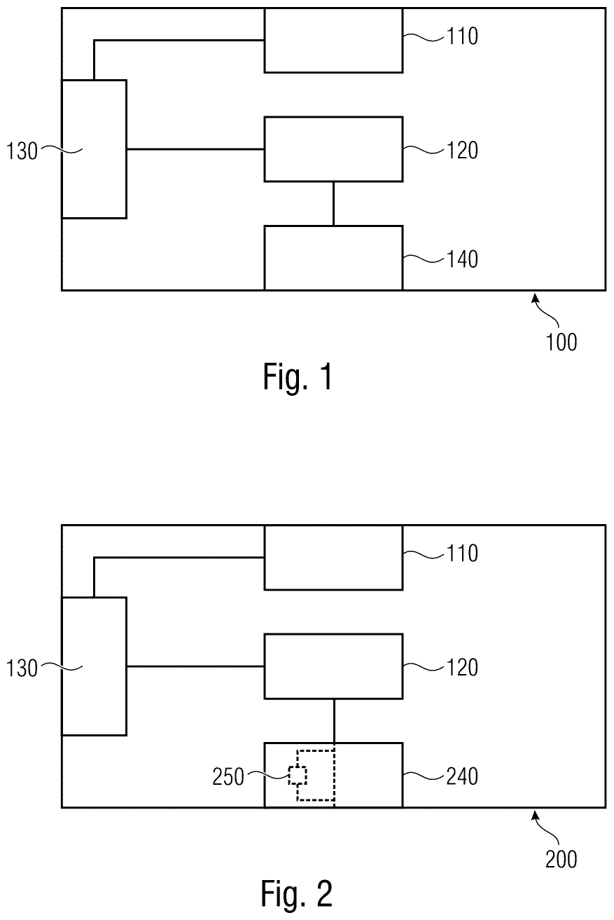

FIG. 1 shows a schematic view of a device for providing an electrical test signal according to embodiments of the present invention. FIG. 1 shows the device 100 for providing an electrical test signal, for performing a continuity test of an electrical line of an object. The device 100 includes a communication module 110 configured to obtain an activation signal to set the device from a passive operating mode to an active operating mode, and to obtain a deactivation signal to set the device from the active operating mode to the passive operating mode. Furthermore, the device 100 includes a signal generator 120 configured to generate the electrical test signal in the active operating mode. Furthermore, the device 100 includes an energy source 130 configured to supply the communication module and the signal generator with energy. Furthermore, the device 100 includes a coupling-in module 140 configured to couple the electrical test signal into the electrical line of the object in the active operating mode.

A method according to the invention may therefore be summarized as follows, e.g., with reference to FIG. 1:

Supplying a communication module 110 with energy of an energy source 130 and obtaining an activation signal by means of the communication module 110 in order to switch from a passive operating mode to an active operating mode, and supplying a signal generator 120 with energy of the energy source 130 in the active operating mode and generating an electrical test signal in the active operating mode by means of the signal generator 120 and coupling the electrical test signal into the electrical line of the object in the active operating mode and obtaining a deactivation signal by means of the communication module 110 in order to switch from the active operating mode to the passive operating mode.

The communication module 110 may optionally be configured to obtain the activation signal or the deactivation signal in a wireless manner. Accordingly, the communication module may be a radio module, for example. Communication may take place via any radio bandwidth, e.g. via Wi-Fi or mobile radio frequencies. In particular, the communication module may be configured to obtain a secure or encrypted activation and/or deactivation signal in order to prevent activation of the device by third parties. In particular, the device may include an antenna or, e.g., a similar unit to improve the radiation and/or reception characteristics.

As previously explained, appropriate wireless communication enables the device to be operated independently of a specific location of the device on or in the object, for example. The inventors have realized that this may have great advantages, especially for large objects and/or for objects with the need to inspect lines in areas that are difficult to access. For example, less personnel may be needed, as technicians are not required to operate the device on site, e.g. to activate the device to generate the test signal and then deactivate it accordingly. In particular, continuity testing may be carried out using an autonomously operating device, such as a drone flying autonomously or automatically, wherein wireless communication with the communication module may be established by a communication unit of the drone. Thus, e.g., corresponding continuity testing may be carried out fully automatically or fully autonomously.

Alternatively, however, the communication module 110 may also be configured to obtain the activation signal and/or the deactivation signal by wire, for example.

In general, the device for providing the electrical test signal according to embodiments may be firmly connected to the object or may only be attached to the object or, more precisely, to the electrical line of the object in the course of an inspection. For example, in the case of a firm structural connection with the object, a communication line may be provided within the object so that the device may be controlled from a predetermined, e.g. easily accessible, position of the object. For example, this may ensure particularly interference-free and robust communication.

Optionally, the energy source 130 may be an energy storage. The energy storage may be replaceable and/or rechargeable. The inventors have realized that such an energy storage has advantages in particular for devices that are connected to the object in the long term, e.g. that are installed in the object. For example, the device may be activated and deactivated remotely with the communication module, in a wireless manner or by wire, in order to carry out inspections without a technician having to access the device itself to establish an energy supply. The energy source in the form of the energy storage may then be replaced or recharged at certain intervals, for example. Accordingly, such an energy storage may be dimensioned in such a way that a large number of continuity tests can be carried out before replacement or recharge is necessary. For example, the energy storage may be an accumulator or a battery, such as a lithium battery. In embodiments, e.g., the battery may be easily replaced by a technician. For example, a corresponding battery may have a capacity of at least 5000 mAh and at most 12000 mAh, e.g. at a voltage of between at least 10 V and at most 14 V. For example, the battery may have a capacity of 8000 mAh with a tolerance of +/−10% at 12 V with a tolerance of +/−10%.

Alternatively, however, the energy source 130 may be configured to be coupled to an external power supply. For example, in the case of objects that are used to generate energy or that are configured to consume energy or power and that are constantly supplied with energy, e.g., existing power electronics may be used to supply the device with energy. The energy source may be configured to be coupled to and decoupled from the external power supply during each inspection, or may be configured to be permanently connected to a corresponding power supply, e.g. in the event that the device is integrated into the object.

Optionally, the coupling-in module 140 may be configured to inductively and/or capacitively couple the electrical test signal into the electrical line of the object in the active operating mode. The inventors have realized that this enables a particularly efficient retrofitting of existing objects for providing the functionality of continuity testing of a line or conductor in the object. For example, this means that no electrical lines of the object need to be exposed in order to couple the test signal into them. Furthermore, this may also provide galvanic decoupling between the device or the coupling-in module and the electrical line, for example. The device may thus be substantially protected from voltage peaks and/or current peaks on the electrical line, for example. Furthermore, this type of coupling has advantages with regard to components that move relative to each other. If the object, such as a wind turbine, is configured to move, it may be advantageous if the coupling-in module is not firmly connected to an electrical line of the object, but that such a connection is able to be inductive.

Alternatively, however, the coupling-in module 140 may also be configured to couple the test signal into the line of the object in the active operating mode by means of a switchable ohmic connection. Thus, e.g., the coupling-in module may be firmly connected to the line, wherein the electrical conductivity may be established or disconnected by means of a switch, for example. In this way, the device may in turn be decoupled from the line, e.g., in order to enable controlled operation or also to protect the device from lightning strikes, e.g., especially in the case of particularly large objects that may attract lightning.

As a further optional feature, the communication module 110 may be configured to be activated in the passive operating mode at timed intervals for a predetermined duration to receive the activation signal. In doing so, the device may consume less energy in the passive operating mode than in the active operating mode. For example, in simple terms, the device may be switched off in the passive operating mode in order to only cyclically activate the communication module to enable transmission of an activation signal. Based on the activation signal, the device may then be switched on accordingly in order to generate and couple in the test signal. For example, this may ensure a long-term energy supply, particularly with an energy storage, so that replacement or recharge intervals for the energy storage can be set as large time intervals.

For example, if the energy source is an energy storage, the communication module 110 may also be configured to transmit a charge status of the energy storage in the active operating mode. Optionally, however, the device may also be configured to perform self-diagnosis and to provide further information about the device by means of the communication module. In both cases, the robustness of the device may be improved, as it may be possible to estimate whether the amount of energy remaining in the energy storage is sufficient to carry out an inspection or to plan maintenance or replacement of the device, for example. Furthermore, recharge or replacement of the energy storage may be planned accordingly.

As a further optional feature, the communication module 110 may further be configured to transmit information about the operating state of the device. In particular, the communication module 110 may be configured to indicate a change from the passive to the active operating state. For example, this may indicate that an activation signal has been successfully transmitted. In addition, this may transmit that the device is ready to perform a continuity test of a conductor of an object or, in other words, to provide the test signal or even that the test signal is already being provided. The inventors have realized that this may have great advantages, especially for objects where the conductors are difficult to access or reach, as otherwise a climber or a drone may be in position to detect the test signal without having certainty that the device for generating the test signal is even ready to do so or, e.g., that there is a fault.

As a further optional feature, the signal generator 120 may be configured to generate a radio-frequency signal and/or a high-frequency signal and/or a clocked low-frequency signal as a test signal. The inventors have realized that, e.g., a high-frequency signal may be used to particularly efficiently generate around the conductor an electromagnetic field that may be detected with a measuring unit. This means that the test signal may also be detected from greater distances around the conductor of the object in order to draw conclusions about the conductor or the line. Furthermore, the high-frequency signal may be used to provide inductive or capacitive coupling into the conductor of the object. In addition, smaller conductor interruptions that may not be relevant for a lightning strike and therefore should not be detected as defects during a continuity test of the conductor, e.g. lightning rod, may also be bridged.

As a further optional feature, the signal generator 120 may be configured to provide impedance matching to the electrical line of the object. In other words, e.g., the generator output may perform impedance matching (radiation) within certain limits, i.e. there may be an attempt to achieve an optimum value depending on the line or conductor, e.g. depending on a length of the line or conductor, or depending on a type of line or conductor. It is to be noted that a uniformly reproducible field strength does not necessarily have to be achieved for all possible variations of electrical conductors, e.g. lightning rods or lightning protection systems. Impedance matching may therefore be used to improve the efficiency of the signal feed, e.g. to minimize signal reflection and losses. This may also extend the replacement interval or recharge interval of an energy storage by saving energy during power supply and signal transmission.

As a further optional feature, the device may be configured to modulate a signal identifier onto the test signal. For example, this means that the test signal may be easily distinguished from other signals so that a robust and accurate evaluation of the continuity test is possible. Furthermore, the use of a signal identifier also enables a large number of test signals to be fed in parallel, e.g. into different conductors, so that the signals can still be kept apart. For example, this may make the inspection of an object having many conductors to be tested particularly time-efficient.

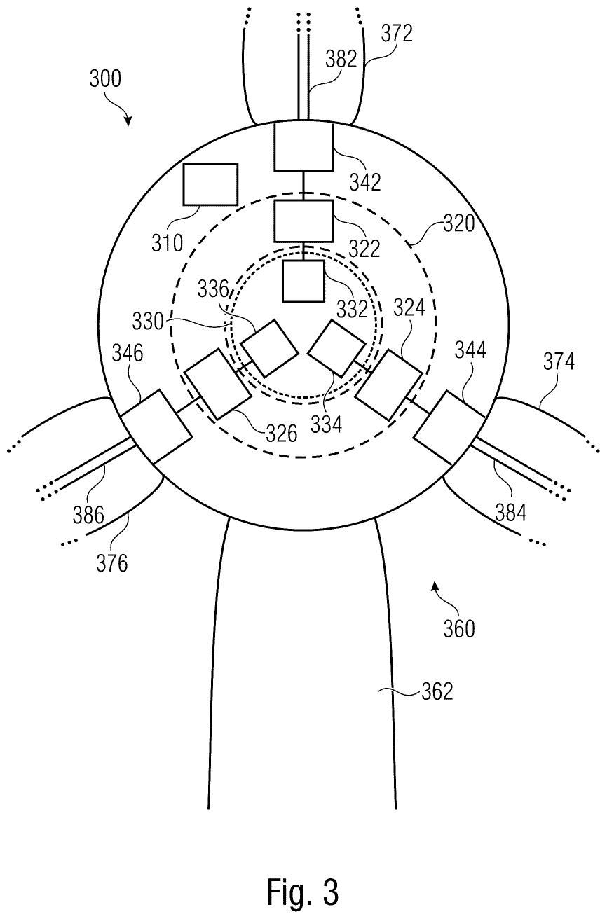

FIG. 2 shows a schematic view of a device with an optional protective diode according to embodiments of the present invention. FIG. 2 shows the device 200 including, in addition to the elements already explained in the context of FIG. 1, a communication module 240. As a further optional feature, the device 200 includes a protective diode 250 configured to protect the device 200 from a voltage and/or current spike on the electrical line of the object. As an optional feature, the protective diode 250 is a suppressor diode connected in parallel with the coupling-in module 240. As indicated in FIG. 2, e.g., the suppressor diode may be connected in parallel with a signal path of the coupling-in module or may optionally also be an element arranged externally outside the coupling-in module, for example. In general, the protective diode may also be arranged on or between other elements of the device. For example, the protective diode may be a transistor diode. For example, such a diode does not need to be derived to ground, but is mounted internally in parallel with the coupling-in module, e.g. an induction coil, and may thus intercept overvoltage pulses. For example, a lightning strike may be intercepted in this way so that the device is not destroyed.

For example, a corresponding protective diode, e.g. in the form of a suppressor diode, may become conductive when a specific voltage threshold is exceeded. A corresponding current peak is then conducted in parallel past the component to be protected, e.g. at the coupling-in module. The diode may absorb the energy internally. Furthermore, a corresponding diode may be configured as a unidirectional or bidirectional diode.

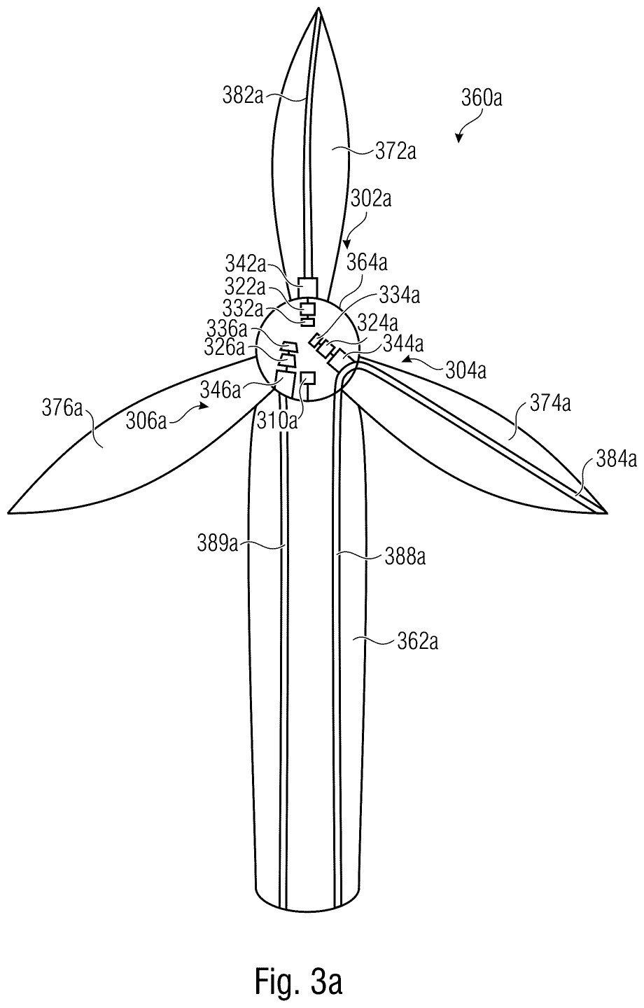

FIG. 3 shows a schematic side view of a wind turbine with a device according to an embodiment of the present invention. FIG. 3 shows a wind turbine 360 with a tower 362, a nacelle 364 and a plurality of rotor blades 372, 374, 376, the rotor blades each having electrical lines 382, 384, 386 in the form of lightning rods (or lightning conductors). More generally, in the context of FIG. 3, it is to be noted that an object may thus be a wind turbine 360 or a rotor blade of such a wind turbine, wherein a device according to the inventive invention is configured to test electrical lines.

Furthermore, FIG. 3 shows the device 300 including a communication module 310, and as shown as an optional feature, a plurality of coupling-in modules 342, 344, 346 corresponding to the plurality of rotor blades. However, it is to be noted that devices according to the present invention may also have only a single coupling-in module. The respective coupling-in modules 342, 344, 346 are each configured to couple the electrical test signal into a respective rotor blade 372, 374, 376 for continuity testing of a respective lightning rod 382, 384, 386. Optionally, the one or more coupling-in modules 342, 344, 346 may be arranged on a lightning rod of a rotor blade, on a supply line to the rotor blade, or integrated in the rotor blade. For example, when building a new system, a device according to the inventive concept may already be integrated into the object or, more precisely, into the rotor blade. In the integrated state, however, in addition to a resistive connection, e.g. with a switch, the coupling-in module may also be configured to inductively or capacitively induce the test signal into the lightning rod or, in general terms, to couple it in.

As a further optional feature, the device 300 includes a plurality of signal generators 322, 324, 326 corresponding to the plurality of coupling-in modules 342, 344, 346, wherein a respective signal generator is configured to generate the respective electrical test signal for coupling into a respective lightning rod in the active operating mode of the device 300. However, it is to be noted that the presence of a plurality of signal generators is merely optional. For example, there may only be a single signal generator 320 with a plurality of signal outputs.

Similarly, as a further optional feature, a single energy source 330 or a plurality of energy sources 332, 334, 336 corresponding to the plurality of signal generators 322, 324, 326 may be configured to supply a respective signal generator with energy.

Again, it is to be noted that a wind turbine as an object is merely an example. For example, radio masts, a wind turbine tower, large antennas, ships such as large container ships, port facilities or other large structures in general may also have electrical lines, e.g., that are difficult to access but still need to be tested.

FIG. 3a shows a schematic side view of a wind turbine having devices according to embodiments of the present invention. FIG. 3a shows a wind turbine 360a with a tower 362a, a nacelle 364a and a plurality of rotor blades 372a, 374a, 376a, the rotor blades each having electrical lines 382a, 384a in the form of lightning rods (lightning rods not shown in rotor blade 376a for clarity reasons). Furthermore, the tower 362a includes a conductor 388a connected to the lightning rod 384a and a second conductor 389a.

Furthermore, FIG. 3 shows a plurality of devices 302a, 304a, 306a each including a coupling-in module 342a, 344a, 346a, a signal generator 322a, 324a, 326a, and an energy source 332a, 334a, 336a, respectively. For the sake of clarity, the respective communication modules are not shown.

As shown as an optional feature in FIG. 3a, e.g., an inventive coupling-in module 342a may be integrated into a rotor blade 372a, e.g. a wing.

Furthermore, a tower 362a may include one or more conductors. Thus, e.g., a device 306a may be configured to provide a continuity test of the conductor 389a.

For example, a corresponding conductor in the tower, e.g. conductor 388a, may be configured to conduct away an overvoltage, e.g. due to a lightning strike, from one or more lightning rods in the rotor blades. Thus, for example, a device 304a may not only perform a continuity test of the lightning rod 384a but also test the conductor 388a connected to the lightning rod 384a at the same time.

For the sake of completeness, it is to be noted that a respective signal generator 322a, 324a, 326a is configured in each case to generate the electrical test signal in the active operating mode of the respective device, for coupling by means of a respective coupling-in module 342a, 344a, 362a, and that a respective energy source 332a, 334a, 336a is configured in each case to supply a respective communication module (not shown) and a respective signal generator 322a, 324a, 326a with energy in the active operating mode of the respective device.

It is also to be noted that the features shown in FIG. 3a are optional, and thus may be used individually or in combination according to embodiments. For example, a tower 362a may have only a single conductor or a plurality of conductors. The different arrangements and embodiments of the devices 302a, 304a, 306a are not to be understood as limiting, but serve to clearly explain different embodiments according to the present invention.

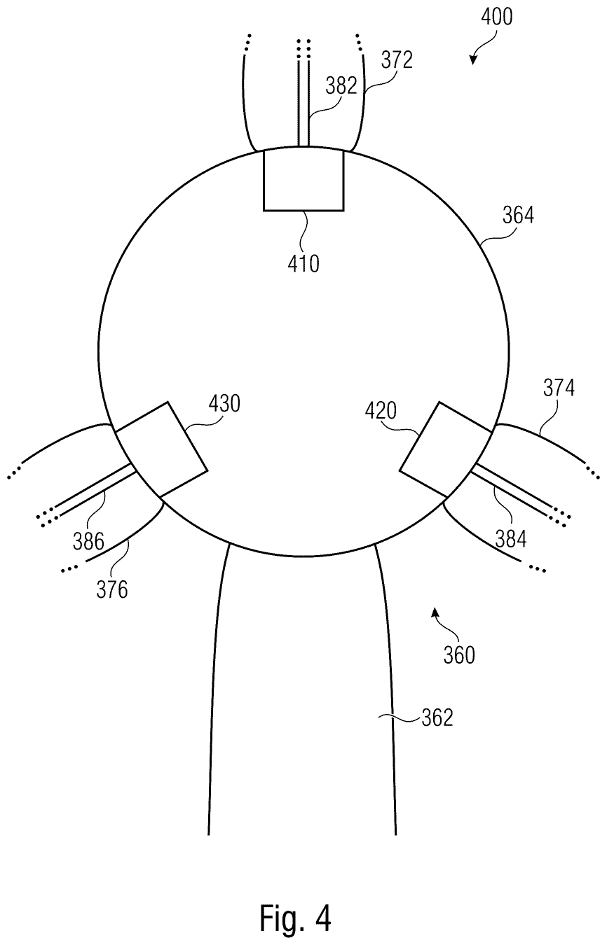

FIG. 4 shows a system for providing electrical test signals according to embodiments of the present invention. FIG. 4 shows a wind turbine 360 according to FIG. 3, and the system 400 including a plurality of devices 410, 420, 430 according to one or more of the embodiments described herein, wherein a respective coupling-in module of a respective device is configured to couple a respective electrical test signal into a respective rotor blade 372, 374, 376 for continuity testing of a respective lightning rod 382, 384, 386. In simple terms, a system 400 according to the invention may thus include a plurality of devices according to the invention corresponding to the number of lines. Thus, a separate device may be provided for each line to be checked, which may accordingly also be individually controlled, i.e. activated and deactivated. Coupling-in modules of the devices 410, 420, 430 may be attached to a lightning rod of a rotor blade or in a supply line to the rotor blade, or may be integrated into a rotor blade.

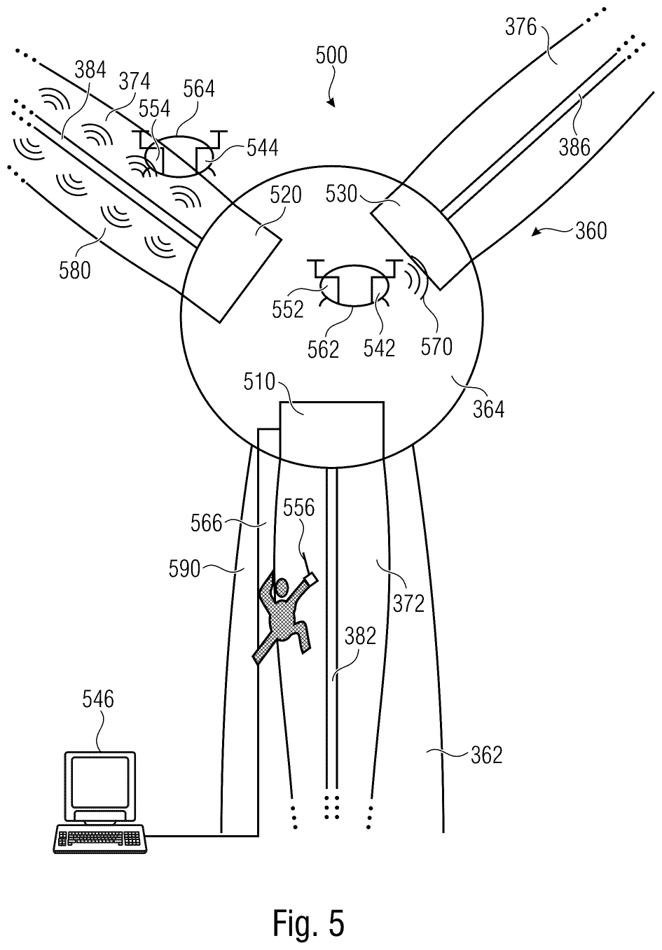

FIG. 5 shows a further system for providing an electrical test signal with further optional features according to embodiments of the present invention. FIG. 5 shows a wind turbine 360 with the features already described in the context of FIG. 3 and FIG. 4. It is to be noted that a wind turbine 360 here is again merely an illustrative example of an object. It should be mentioned again that cranes, antenna masts, radio masts, large ships or, e.g., entire port facilities may also have electrical lines that need to be tested at regular intervals.

With reference to FIG. 5 and a system 500, a large number of embodiments are explained below. It is to be noted that, unless otherwise explained, individual features, details and functionalities are highlighted here together to illustrate the inventive functionality, but these do not all have to be present together at the same time in embodiments.

As an example, the system 500 includes a plurality of devices according to one or more of the embodiments explained, namely devices 510, 520 and 530, the devices being arranged in proximity to the lightning rods of the rotor blades to couple a test signal into the corresponding rotor blade 372, 374, 376 or, more specifically, into the corresponding lightning rod 382, 384, 386, by means of a respective coupling-in module.

It is again to be pointed out that, e.g., the system may only have one device having a plurality of coupling-in modules so that the test signal may be fed into the lightning rods 382, 384, 386 via the plurality of coupling-in modules, e.g., from a common signal generator or from a plurality of signal generators.

Furthermore, the system 500 includes a communication unit, e.g. a communication unit 542 and/or a communication unit 544 and/or a communication unit 546, configured to transmit the activation signal and the deactivation signal to a communication module of one of the devices 510, 520, 530.

The system 500 further includes a measuring unit, e.g. a measuring unit 252 or a measuring unit 554 or a measuring unit 556, configured to detect the test signal.

FIG. 5 accordingly shows several options for the communication unit and the measuring unit and measuring unit, which will be explained in more detail below. It is to be noted that the system and in particular the inventive methods may have such units individually, together, in combination or individually. This will be explained in more detail in the following explanation.

For example, a drone 562 may be used to perform continuity testing of an electrical wire of an object. It is to be noted that the system 500 may optionally include the drone 562 as well. For example, the drone may be launched from the ground using a laptop computer. The drone may be configured to subsequently fly, e.g. autonomously, semi-autonomously or automatically or by manual control, to one of the devices 530 and thus, e.g., to the rotor hub 364, as shown in FIG. 5. To activate the device 530, the activation signal may now be transmitted to the communication module of the device 530 by means of the communication unit 542. Accordingly, a communication unit according to the inventive device, such as the communication unit 542, may be configured to be attached to a drone.

For example, in order to be able to receive a corresponding activation signal 570, the communication module of the device 530 may be activated at time intervals for a predetermined duration. Accordingly, the communication unit may be configured to provide the activation signal 570 during a time span that is greater than a time span between two activations of the communication module.

Accordingly, the activation signal 570 may be received by the device 530 or, more precisely, by the communication module of the device 530 in order to switch from the passive operating mode to the active operating mode. Consequently, a method of the invention may include transmitting the activation signal by means of the communication unit 542 to the communication module during a time span greater than a time interval between two activations of the communication module. Optionally, information about the operating state of the device may be transmitted back from the communication module of the device 530 to the communication unit 542 accordingly. Accordingly, in the active operating mode of the device, the test signal may then be introduced into the lightning rod. Starting from an activated device, a drone, as shown for example with the drone 564, may automatically, autonomously, semi-autonomously, or even manually fly along a rotor blade 374. The drone may have a measuring unit that is configured to be attached to a drone, e.g. like the measuring units 552 and 554 in FIG. 5.

It is to be noted that the drones 542 and 544 and, correspondingly, the communication units 542 and 544 and the measuring units 552 and 554 are each the same objects that perform the steps explained herein in sequence.

In the following, it is assumed that the device 520 is in the activated state, e.g. by having been previously activated, as explained with the drone 562 and the rotor blade 376. Accordingly, device 520 may couple a test signal 580 into the conductor 384 by means of the associated signal generator and the coupling-in module. The coupling may be inductive, capacitive or via ohmic switchable connection.

The measuring unit 554 may optionally be configured to detect the test signal 580 during an inspection flight of the drone 564 along the object, e.g. along the rotor blade 374. Accordingly, an interruption of the conductor may be inferred if such a signal is weaker than expected or not present. Subsequently, e.g., the drone 564 may return to a respective device, such as the device 530, as previously explained, or the device 552, and then transmit the deactivation signal, e.g. in a position as shown with drone 562, to terminate the coupling of the test signal. Accordingly, an automatable method of continuity testing of lightning rods may be provided.

It is to be noted, however, that the communication unit 542 may also be used to transmit the activation and/or deactivation signal from any position on a flight path of the drone 562, 564, e.g. during a flight from one rotor blade to a next rotor blade, e.g. from a hub of the wind turbine, or for example from a rotor blade tip.

In general terms, the object may accordingly be approached by flight with a drone 562, 564, e.g. automated, semi-autonomous, autonomous or manual, the drone comprising the measuring unit 552, 554. Subsequently, an activation signal may be transmitted to a communication module of a device 520, 530 by means of a communication unit 542, 544.

It is to be noted here that, e.g., there may also only be a single device, with a single communication module, e.g., but a plurality of coupling-in modules for coupling the electrical test signal, so that the activation signal is only transmitted to that single communication module, for example.

The drone may then be used to fly along the object and the test signal 580 or the plurality of test signals of several rotor blades may be detected by means of the measuring unit 552, 554. After flying off, the one or more devices may then be switched back to passive operating mode, e.g. switched off, by means of a deactivation signal.

The detected test signal may then be evaluated. For example, an inventive method may include comparing the detected test signal with a reference signal. For example, the reference signal may be a theoretical reference signal that can be determined using nominal data of the test signal and the lightning rod, or also, e.g., a historical reference signal that was detected, e.g., during a previous measurement. In particular, this may also provide information about a trend, such as a degradation of the lightning rod over time, e.g. to predict maintenance that may not be necessary immediately but should be carried out in the long term. In this way, information about damage to the electrical line or lightning rod may be determined.

In general, the data stored by the measuring unit may be, in addition to the actual detected value of the test signal, at least one of a time information, an absolute position information of the drone, a distance information and/or a position information of the drone with respect to the rotor blade. For example, the drone may have a GPS receiver or determine its own position using relative localization systems.

The result of such an evaluation based on the detected information may be used to localize a damaged area and plan a replacement or repair. For example, climbers 566 may be used for this purpose. For particularly precise localization, a measuring unit 556 may be a portable device, e.g., so that a climber in the immediate vicinity of the rotor blade may determine a damage site more precisely. A signal line 590 is shown as an example for activating the device 510. Accordingly, the activation signal may be transmitted by wire to the communication module of the device 510 by means of a communication unit 546. In the case of the wind turbine, e.g., if the device 510 is firmly connected to the rotor hub, this may be an electrical line that is laid along the tower to the base of the turbine. Thus, e.g., a laptop, which may also be used to control a drone, e.g., may be used to activate the device 510. Accordingly, it is to be noted that a corresponding wired signal transmission may also be used with embodiments using drones. Alternatively, however, e.g., a climber 566, may also carry a portable communication unit that may be used to activate a corresponding device 510 as explained in the course of drone 562.

In summary, the activation signal may therefore be transmitted by wire or in a wireless manner by means of a communication unit to the communication module of a device or the device, e.g. if only one device is installed in the wind turbine, with a plurality of coupling-in modules. Subsequently, e.g., a climber may scan the lightning rod by means of a handheld device 556 and detect a corresponding test signal. After detection of the test signal, the corresponding device 510 may in turn be deactivated by means of the communication module. A measuring unit 556 may be able to transmit the measured data in a wireless manner, e.g. to enable an immediate evaluation during the inspection, so that, e.g., the exact position of the damaged area can be determined directly and a repair can be initiated directly.

It is to be pointed out once again that several optional procedures according to the invention were presented in the explanation of FIG. 5, but these may be used individually or in combination. For example, a drone may be used to activate a large number of devices one after the other and in each case iteratively couple a test signal into one of the rotor blades in order to iteratively fly along these rotor blades one after the other and deactivate the activated device again after each flight in order to activate another device until all the corresponding lightning rods have been inspected. However, a drone relay may also be used so that all devices are activated simultaneously and several rotor blades or all rotor blades are flown to simultaneously, or, in the case of a single device, that device is activated so that the device activates a plurality of coupling-in modules in order to introduce respective test signals into respective lightning rods with the help of one or more signal generators. As explained above, the flight may be manual, automated, autonomous, or semi-autonomous. For example, a semi-autonomous flight may include a correction of a, e.g. predetermined, flight direction or a distance (e.g. from the object), e.g., via an additional measuring system, e.g. LIDAR. Alternatively, the activation and deactivation may of course also be carried out manually, e.g. by climbers, as well as scanning the corresponding conductor of the wind turbine.

In the following, further embodiments, and previously explained embodiments, summarized in other words, for objects in the form of wind turbines or rotor blades of wind turbines, are discussed.

According to an embodiment, for example, the coupling-in module may be a clamp, e.g. an induction clamp. For example, the communication module may be configured as a radio module or integrated radio module, e.g., wherein the radio module may be configured to switch the device from the passive operating mode, e.g. a sleep mode, to the active operating mode, e.g. an active mode or an active mode.

For example, a drone having a measuring unit may be used to detect the test signal so that, e.g., after an inspection flight, e.g. by means of the radio module, the device may be switched back to passive operating mode, e.g. sleep mode.

For example, for testing a lightning protection system of a wind turbine, the core idea according to such embodiments is the non-invasive injection of an electromagnetic field into the lightning protection system and the contactless, e.g. autonomous, a flight along the rotor blades by means of the drone, which may be equipped with a measuring unit, e.g. a special sensor for field measurement. This measurement may use special measurement technology and mathematical/algorithmic processing to quickly, efficiently, and accurately determine the functionality of the lightning protection system.

In simple terms, embodiments are therefore based on, e.g., inductively feeding an electric field into the lightning protection system of the rotor blade and measuring the radiated electric field with a measuring unit, such as a field sensor on a drone.

According to embodiments, it is possible to precisely localize any damaged areas that are detected and. e.g., may be subsequently tracked at any time with another measuring unit, e.g. a separate hand sensor for the purpose of repair.

As explained above, e.g., the energy source may be configured as a replaceable energy storage. For example, a lithium battery or a lithium accumulator may be used for this purpose. (It is to be noted once again that, according to embodiments, a cable may also be used as an alternative for supplying energy to the device by means of an external power supply).

As an example, such an energy storage may have a capacity of approx. 8000 mAh (e.g. with a tolerance of up to +/−5% or with a tolerance of up to +/−10% or with a tolerance of up to +/−50% or with a tolerance of up to +/−100% or with a tolerance of up to +/−1000%), e.g. at approx. 12 V (e.g. with a tolerance of up to +/−5% or with a tolerance of up to +/−10% or with a tolerance of up to +/−50% or with a tolerance of up to +/−100% or with a tolerance of up to +/−1000%).

In embodiments, e.g., such an energy storage may be replaced with little effort, e.g. with a handle. For this purpose, e.g., the device may have simple plug-in and snap-in connections for such an energy storage.

As explained above, the communication module, e.g. the radio module, may optionally be activated in the passive operating mode at time intervals for a predetermined duration to receive the activation signal. A corresponding replaceable energy storage may be designed for a service life of many years so that a device according to the inventive invention can operate for long periods of time without requiring any special maintenance.

For example, power consumption in the passive operating mode, e.g. in sleep mode, may be composed as follows:

For example, the electronics may require approx. 15 micro amps in the sleep mode and may be “woken up” every 60 sec for approx. 0.1 sec to query the radio signal-approx. 15 mA for 0.1 sec. This results in an annual consumption of approx. 500 mAh or 2000 mAh for 4 years.

A power consumption in the active operating mode, e.g. an inspection mode, may be composed as follows for the example of lightning rod inspection on a wind turbine:

Approx. 800 mA, i.e. with a maximum inspection time of 15 minutes per wing, approx. 4000 mAh for approx. 20 inspections.

Accordingly, for the previous example of the energy storage system having approx. 8000 mAh at approx. 12 volts, e.g., when assuming or calculating with 2-3 inspections per year, e.g. after a lightning strike (e.g. the legal requirement is a maximum of 1 inspection every 2 years), and when taking into account a certain self-discharge of the energy storage system, e.g. the Li battery, the battery may only need to be replaced approx. every 6 years (e.g. normal prescribed service in the system is every 2 years) as part of the prescribed service.

Thus, a device according to the invention may operate for long periods without maintenance. As explained above, e.g. during each or at least some inspections (e.g. in the active operating mode, i.e. when the device is active), the charge state of the energy storage (e.g. battery) may optionally be queried by the drone via the communication module (e.g. radio module) each time for safety reasons.

According to further embodiments, as already explained above, the device or only the coupling-in module, e.g. in the form of an induction clamp, may be firmly connected to the wind turbine or a rotor blade of the wind turbine. For example, the device or the coupling-in module of the device may be attached to the lightning rod of a rotor blade and/or in a supply line to the rotor blade or the device or the coupling-in module may be integrated into a rotor blade, for example.

For example, to operate the device, e.g. a device described above, the coupling-in module, e.g. in the form of an induction clamp, may be attached (e.g. glued) once to the lightning rod at the start of the blade by a service team and may remain there for the entire life cycle of the system (wind turbine, e.g. approx. 25 years). The coupling-in module may be integrated in the hub of the wind turbine, on a rotor blade flange or in a rotor blade itself.

A major advantage of embodiments with galvanic isolation between the coupling-in module and the line of the object, e.g. with inductive coupling, e.g. a non-invasive induction process according to the inventive method, is that the device (e.g. the coupling-in module in the form of an induction clamp) does not have to be directly (electrically) connected to the lightning rod, so that damage to the system or the device may not occur, e.g. in the event of a lightning strike. Optionally, e.g., protective diodes, e.g. in the form of so-called transil diodes, may be arranged or attached between the coupling-in module (according to embodiments, generally configured as an induction coil or induction ring, for example) and the output transistors (e.g. of the signal generator) for additional protection. Corresponding embodiments may enable the use of such diodes in the first place.

In the following, an example of an inspection procedure according to embodiments will be explained on the basis of a wind turbine for measuring lightning protection according to embodiments. For example, an inventive device as explained above may be used for this purpose. For example, a device, e.g. having a coupling-in module in the form of a clamp, e.g. an induction clamp, may be arranged on each rotor blade, or simply put, wing, of the wind turbine. Furthermore, the detection of the test signal may be realized by means of a drone including a measuring unit. Thus, e.g., the following sequence of steps may be carried out according to an embodiment.
1. The drone flies, e.g. autonomously, to the blade hub of the wind turbine (as explained above, this is only one option according to embodiments, e.g. a rotor blade tip may also be flown to, and a manual, automated or semi-autonomous flight may also be carried out as an option).
2 The drone initiates the activation signal, e.g. a radio signal, to activate the first device (e.g. wing 1), or simply put, to “wake it up”. The drone waits for a defined time interval, e.g. for approx. 75 seconds, in order to actually catch the wake-up interval (e.g. every 60 seconds) (in other words, a waiting time, e.g. a time in which the activation signal is transmitted, may be longer than a period between two activations of the communication module in the passive operating mode). In addition, it optionally receives feedback from the device via the radio module that the device is in the active operating mode, e.g. active
3. The drone flies along the wing, e.g. autonomously (or manually, or automated, or semi-autonomously), and returns to the hub (or e.g. returns to the rotor blade tip or to another rotor blade, or remains at the wing tip after a take-off from the hub, or remains at the hub after a take-off from the wing tip), and switches the device back to passive operating mode, e.g. sleep mode
4. The drone then wakes up the next device (e.g. the next rotor blade), etc.

In the following, the advantages of devices including coupling-in modules in the form of clamps, e.g. lightning protection clamps, according to embodiments, with said modules being firmly connected to the wind turbine, will be discussed using an example.

For some procedures, it may be necessary (e.g. required by law for safety reasons if technicians have to climb out of the hub into the wing attachment) for two service workers to travel into the nacelle (hub) with the elevator in order to be able to attach the clamps to the lightning protection cable at the respective wing attachments (flange).

The energy source, e.g. in the form of a power supply unit, may then be connected to each of the three clamps (one device per rotor blade) via a cable, e.g. 10 m long, and the clamps may be switched on/off in sequence by a service technician on the power supply unit, e.g. via a rotary switch, depending on the position of the drone (blades 1, 2 or 3).

The drone may then fly along the wing with a speed of e.g. 0.25 m/sec (i.e. e.g. a speed of at least 0.1 m/sec and at most 0.3 m/sec or of at least 0.2 m/sec and at most 0.3 m/sec) (distance e.g. approx. 5 m (i.e. e.g. a distance of at least 4 m and at most 6 m or of at least 1 m and at most 10 m)—optionally by means of manual, automated, autonomous or semi-autonomous flight)—e.g. from the wing base (flange) to the wing tip and may scan the radiated electric field of the test signal. This means that with a wing length of 60 meters, e.g., the entire lightning protection inspection for a wing takes approx. 4 minutes. Afterwards, the drone may also optionally fly autonomously (or manually, or automated, or semi-autonomously) at a higher speed back to the hub (taking approx. 1 minute, for example) or to another point on the wind turbine, e.g. a neighboring blade tip. The service engineer may then switch to the next pair of clamps and the next blade may be inspected. This means that the entire inspection (flight time of the drone without scaffolding) including approach/departure may take approx. 25 minutes, for example.

Optionally, according to embodiments, areas of the object may be inspected in particular or additionally. For example, individual areas of the wing, e.g. receptors, may also be inspected. However, this may increase the inspection time by several minutes.

For example, advantages of embodiments in which the device is firmly connected to the object are that for setting up and dismantling the devices, and thus, e.g., the clamps, two service technicians do not have to take the elevator into the tower. This may eliminate the need for one service technician to travel back down to operate the drone while the other service technician operates the power supply unit from the hub. This may also eliminate the need for the second technician to travel back up again to remove the clamps once the inspection has been completed.

This can save a great deal of time. However, it is to be noted that embodiments with devices that have to be assembled and dismantled, e.g. as explained above, still have great advantages over conventional approaches, e.g. with rope climbers.

For example, an average inspection with a system according to the invention may take approx. 1.5 hours (compared to the conventional method with a rope climber taking approx. 8 hours). According to embodiments, this duration can be further reduced with devices permanently arranged on the object.

Embodiments therefore have great advantages, especially for objects that are difficult to access. In the case of offshore installations (approach by ship, height of the installations), a complete inspection may take several days. In addition to the personnel costs, the downtime costs due to downtime during the inspection play an important role (e.g. up to € 2000 per hour). According to an embodiment, major time and cost savings are therefore possible.

Methods of the invention thus make it possible to eliminate the disadvantages described above and to provide an extremely effective system for testing the continuity of a lightning rod of a wind turbine.

According to further embodiments of the present invention, the signal generator may induce a tuned signal into the lightning rod at the base of a rotor blade and thereby generate a test signal, e.g. a nearly constant electric near field, along the rotor blade within a frequency range approved by the grid agency. According to embodiments, the signal may be induced non-invasively in the lightning protection cable.

According to embodiments, e.g. according to embodiments explained above, e.g., the device may have a coupling-in module in the form of an induction clamp, or, e.g., a coupling-in module in the form of an induction ring.

For example, when building a new wind turbine, an induction ring may be integrated directly into a rotor blade. Put simply, a corresponding induction ring may be slid over a lightning rod on the rotor blade. Alternatively, a cable in an existing turbine may be cut open to attach the induction ring. An induction ring may have advantages with regard to the signal quality of a test signal fed in. Furthermore, a feed-in using an induction ring may also be particularly robust.

For example, an induction clamp may be configured to only partially enclose a lightning rod (e.g. be a clamp with an open end) in order to induce the test signal. For example, this means that no cables need to be cut open (compared to conventional methods of with the aid of continuity measurements, e.g. ohmic continuity measurements) or any other interventions need to be carried out.

According to such embodiments, the signal generator may directly have a connection optimized to a corresponding induction ring or to a corresponding induction clamp and adapted via impedance, e.g. exactly or at least approximately.

Any deviations from a standard or default impedance value (e.g. caused by different lengths of lightning protection cables, branched lightning protection structures, etc.) may optionally be automatically adjusted by an output stage of the signal generator. Each device, e.g. including an induction clamp, may optionally have its own communication module in the form of a radio module (e.g. having 868 MHZ, ISM radio) and may be individually controlled from the ground by an operator via radio for measurement.

For example, this has the advantage that all three rotor blades of a wind turbine may be connected simultaneously before the measurement and, for the actual measurement, the signal feed into the rotor blades may be controlled individually by the operator via radio from the ground. It is to be noted that the devices, e.g. coupling-in modules of the devices in the form of induction clamps, may also be permanently attached to the lightning rods of the rotor blades or to corresponding supply lines.

To avoid measurement inaccuracies due to interference on the ISM band (13.56 MHZ), which is used extensively, e.g., an identifier may also be optionally modulated onto the test signal, which is filtered out by the sensor processor (e.g. the measuring unit) and used exclusively for calculating the values. For example, this may reliably eliminate influences on the measurements caused by external signals or interference.

Optionally, other, e.g. alternative, frequencies, e.g. radio frequencies and/or, e.g. clocked, low frequencies may also be used.

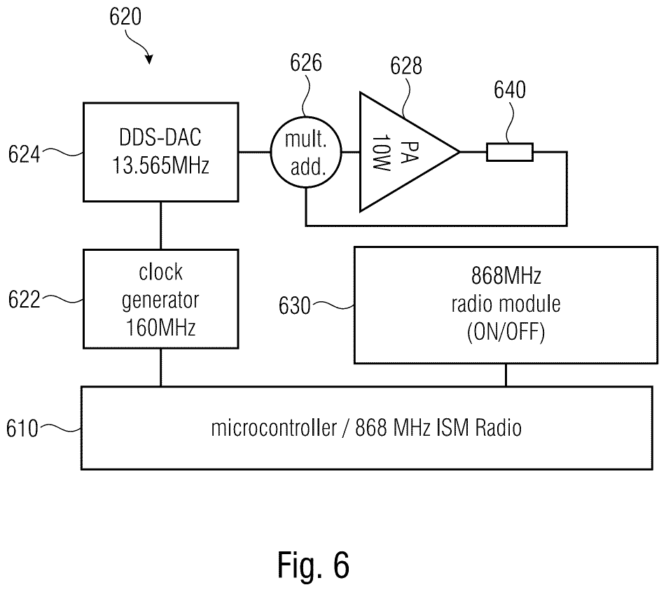

FIG. 6 shows a schematic block circuit diagram of electronics of a device according to an embodiment of the present invention. FIG. 6 shows a microcontroller 610 configured, e.g., to control the communication module 630, e.g. to switch on the communication module 630 (for example for the active operating mode or for a cyclic standby to receive the activation signal in the passive operating mode) and/or to switch it off (for example for the passive operating mode). As an optional example, the communication module 630 is a radio module configured to transmit and/or receive on a frequency of 868 MHZ. Furthermore, the electronics of the device include a signal generator 620 that optionally includes a clock generator 622 with an optional clock frequency of 160 MHZ, a direct digital synthesis digital-to-analog converter (DDS-DAC) configured to provide an analog signal, e.g. a sinusoidal analog signal with a frequency of 13.565 MHZ, as optionally shown, and a multiplier and/or adder 626 (Mult. Add.) and a signal amplifier 628 (power amplifier-PA 10 W), e.g. having a power of at least 1 watt and at most 20 watts, e.g. having a power of 10 watts (e.g. with a tolerance of at least +/−5%) or e.g. having a power of at least 1 watt and at most 5 watts, e.g. having a power of 2 watts (e.g. with a tolerance of at least +/−5%).

In the example of FIG. 6, an impedance matching with respect to the line of the object prevails as an optional feature so that the coupling-in module and the line of the object are represented as an ohmic resistor 640.

In general, e.g., the output stage of the signal generator may be a differential output stage.

In the following, coupling-in modules according to an embodiment are explained again in other words and with further optional details

As explained above, according to embodiments, the test signal may be induced into the conductor of the wind turbine in the form of a lightning protection cable using a non-invasive method of the invention with the aid of a device including a coupling-in module in the form of an induction clamp, an induction ring, or a measuring ring.

Embodiments include coupling-in modules in the form of induction clamps. Such methods may have a number of significant advantages:
a) The lightning protection cable does not have to be interrupted or disconnected from the ground. For example, the induction clamp may be pushed under the cable at an accessible point.
b) If the cable is permanently laminated, the induction clamp may simply be placed on the cable and then only needs to be attached (e.g. using adhesive tape).
c) The signal (generator output) is only adapted to the induction clamp once, e.g., so there are no problems with incorrect adaptations including standing waves with different rotor blade structures and lengths.
d) With optimal or at least approximately optimal matching, there no or only very few oscillations or interference waves—e.g. the signal may only or essentially propagate in the specified e.g. extremely narrowband frequency range.
e) Consistent, repeatable measurement behavior with the same blade designs.

According to embodiments, e.g., the test signal generated along the rotor blade, e.g. a vertically radiating field with the field strength E (linear near field), may decrease quadratically to the distance between the drone and the rotor blade. The counterpart, e.g. the measuring unit, may be a highly sensitive electric field sensor, e.g. a 1D, 2D or 3D field sensor, e.g. with an extremely low bandwidth and high sampling rate, which may be integrated into the optional autonomously (or e.g. manually or automated or semi-autonomously) flying drone as a payload. If the sensor receives no signal or insufficient signal strength at the tip of the rotor blade, the lightning rod along the rotor blade may be damaged or interrupted.

According to some embodiments, the conductor may form a (grounded) monopole—e.g. the conductor does not have to be disconnected but may remain connected to ground—e.g. and the signal generator of the test system, i.e. the device, may operate at a frequency of 13.56 MHz in the ISM shortwave band (e.g. with a tolerance of up to +/−5% or with a tolerance of up to +/−10% or with a tolerance of up to +/−50% or with a tolerance of up to +/−100% or with a tolerance of up to +/−1000%).

The test signal generated by the induction, e.g. a vertical constant electric near field, may be detected by a measuring unit, e.g. by a field sensor on a drone, flying along the rotor blade, e.g., and a continuity test of the lightning rod is carried out based on the radiated field.

For example, the direction (e.g. when using a 3D field sensor) and intensity of the detected field strength may be evaluated to determine whether the conductor is interrupted. If the measurement shows a continuous field within predetermined tolerances, e.g., it may be concluded that the line is not interrupted, i.e. that the lightning rod is functional. If the field strength deviates from a predetermined range at one or more positions along the conductor, this may indicate an interrupted line, for example.

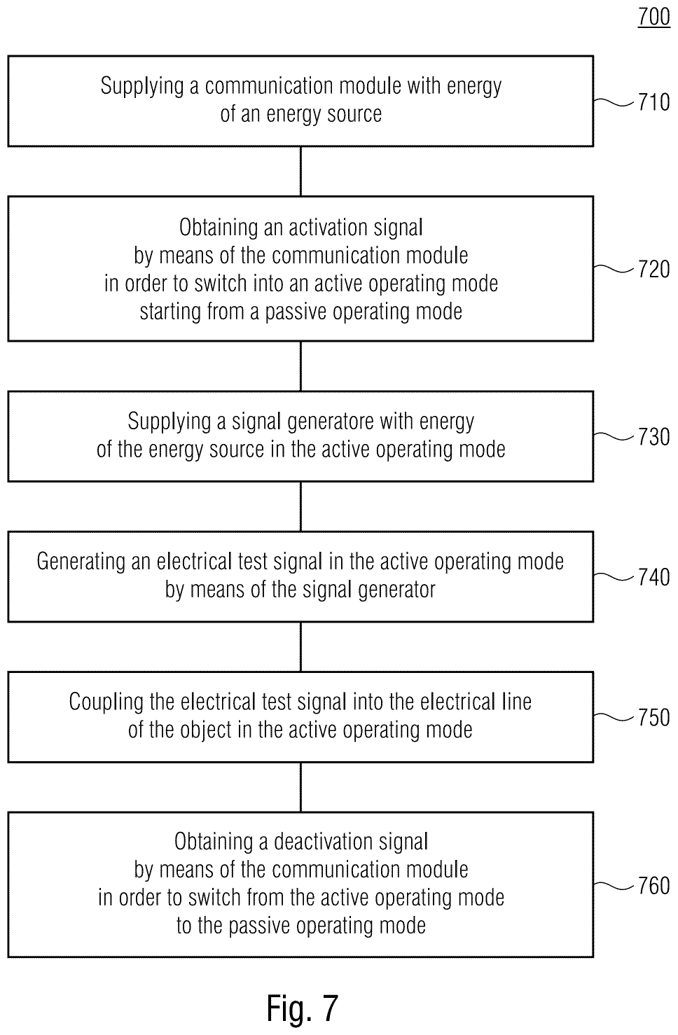

FIG. 7 shows a schematic block diagram of a method according to an embodiment of the present invention. FIG. 7 shows a method 700 for performing a continuity test of an electrical line of an object, including supplying (710) a communication module with energy of an energy source and obtaining (720) an activation signal by means of the communication module in order to switch from a passive operating mode to an active operating mode and supplying (730) a signal generator in the active operating mode with energy of the energy source and generating (740) an electrical test signal in the active operating mode by means of the signal generator and coupling (750) the electrical test signal into the electrical line of the object in the active operating mode and obtaining (760) a deactivation signal by means of the communication module in order to switch from the active operating mode to the passive operating mode.

All lists of materials, environmental influences, electrical properties and optical properties given herein are to be regarded as exemplary and not exhaustive.

Even though some aspects have been described within the context of a device, it is understood that said aspects also represent a description of the corresponding method, so that a block or a structural component of a device is also to be understood as a corresponding method step or as a feature of a method step. By analogy therewith, aspects that have been described within the context of or as a method step also represent a description of a corresponding block or detail or feature of a corresponding device. Some or all of the method steps may be performed while using a hardware device, such as a microprocessor, a programmable computer or an electronic circuit. In some embodiments, some or several of the most important method steps may be performed by such a device.

Depending on specific implementation requirements, embodiments of the invention may be implemented in hardware or in software. Implementation may be effected while using a digital storage medium, for example a floppy disc, a DVD, a Blu-ray disc, a CD, a ROM, a PROM, an EPROM, an EEPROM or a FLASH memory, a hard disc or any other magnetic or optical memory which has electronically readable control signals stored thereon which may cooperate, or cooperate, with a programmable computer system such that the respective method is performed. This is why the digital storage medium may be computer-readable.

Some embodiments in accordance with the invention thus comprise a data carrier which comprises electronically readable control signals that are capable of cooperating with a programmable computer system such that any of the methods described herein is performed.

Generally, embodiments of the present invention may be implemented as a computer program product having a program code, the program code being effective to perform any of the methods when the computer program product runs on a computer.

The program code may also be stored on a machine-readable carrier, for example.

Other embodiments include the computer program for performing any of the methods described herein, said computer program being stored on a machine-readable carrier.

In other words, an embodiment of the inventive method thus is a computer program which has a program code for performing any of the methods described herein, when the computer program runs on a computer. The data carrier, the digital storage medium, or the recorded medium are typically tangible, or non-volatile.

A further embodiment of the inventive methods thus is a data carrier (or a digital storage medium or a computer-readable medium) on which the computer program for performing any of the methods described herein is recorded. The data carrier, the digital storage medium or the computer-readable medium are typically tangible and/or non-volatile or non-transitory.

A further embodiment of the inventive method thus is a data stream or a sequence of signals representing the computer program for performing any of the methods described herein. The data stream or the sequence of signals may be configured, for example, to be transferred via a data communication link, for example via the internet.

A further embodiment includes a processing means, for example a computer or a programmable logic device, configured or adapted to perform any of the methods described herein.

A further embodiment includes a computer on which the computer program for performing any of the methods described herein is installed.

A further embodiment in accordance with the invention includes a device or a system configured to transmit a computer program for performing at least one of the methods described herein to a receiver. The transmission may be electronic or optical, for example.

The receiver may be a computer, a mobile device, a memory device or a similar device, for example. The device or the system may include a file server for transmitting the computer program to the receiver, for example.

In some embodiments, a programmable logic device (for example a field-programmable gate array, an FPGA) may be used for performing some or all of the functionalities of the methods described herein. In some embodiments, a field-programmable gate array may cooperate with a microprocessor to perform any of the methods described herein. Generally, the methods are performed, in some embodiments, by any hardware device. Said hardware device may be any universally applicable hardware such as a computer processor (CPU), or may be a hardware specific to the method, such as an ASIC.

The devices described herein may be implemented using, e.g., a hardware device, or using a computer, or using a combination of a hardware device and a computer.

The devices described herein, or any components of the devices described herein, may be implemented at least in part in hardware and/or in software (computer program).

The methods described herein may be implemented, e.g., using a hardware device, or using a computer, or using a combination of a hardware device and a computer.

The methods described herein, or any components of the methods described herein, may be configured at least in part by hardware and/or by software.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. Device for providing an electrical test signal, for performing a continuity test of an electrical line of an object, comprising:
a communication module configured to:
acquire an activation signal to switch the device from a passive operating mode to an active operating mode, and
acquire a deactivation signal to switch the device from the active operating mode to the passive operating mode; and
a signal generator configured to generate the electrical test signal in the active operating mode;
an energy source configured to supply the communication module and the signal generator with energy, and
a coupling-in module configured to:
couple the electrical test signal into the electrical line of the object in the active operating mode.

2. Device according to claim 1, wherein the communication module is configured to acquire the activation signal and/or the deactivation signal in a wireless manner.

3. Device according to claim 1, wherein the communication module is configured to acquire the activation signal and/or the deactivation signal in a wired manner.

4. Device according to claim 1,
wherein the energy source comprises at least one of a replaceable energy storage and/or a rechargeable energy storage; and/or
wherein the energy source is configured to be coupled with an external power supply.

5. Device according to claim 1,
wherein the coupling-in module is configured to inductively couple the electrical test signal into the electrical line of the object in the active operating mode; and/or
wherein the coupling-in module is configured to capacitively couple the electrical test signal into the electrical line of the object in the active operating mode.

6. Device according to claim 1, wherein the coupling-in module is configured to, in a galvanically isolated manner, be attached to the electrical line such that the device is substantially protected from a voltage and/or current spike on the electrical line.

7. The device according to claim 1, wherein the coupling-in module has an electrically switchable ohmic connection with the line of the object in order to couple the electrical test signal into the electrical line of the object in the active operating mode.

8. Device according to claim 1, configured to:
reduce energy consumption of the device in the passive operating mode compared to active operating mode, and
activate the communication module in the passive operating mode at time intervals for a predetermined duration for acquiring the activation signal.

9. Device according to claim 1,
wherein the energy source comprises at least one of a replaceable energy storage and/or a rechargeable energy storage; and
wherein the communication module is configured to transmit a charge state of the energy storage in the active operating mode.

10. Device according to claim 1, wherein the communication module is configured to transmit an information about the operational state of the device.

11. Device according to claim 1,
wherein the electrical test signal is a high-frequency signal, a radio-frequency signal, a low-frequency signal and/or a clocked low-frequency signal.

12. Device according to claim 1, wherein the signal generator is configured to enable impedance matching to the electrical line.

13. Device according to claim 1, wherein the device comprises at least one protective diode, and
wherein the protective diode is configured to protect the device from a voltage and/or current spike on the electrical line.

14. Device according to claim 13, wherein the protective diode is a suppressor diode and wherein the suppressor diode is connected in parallel with the coupling-in module.

15. Device according to claim 1, wherein the test signal comprises a modulated signal identifier.

16. Device according to claim 1,
wherein the object is a wind turbine with a plurality of rotor blades, the rotor blades each comprising electrical lines in the form of lightning rods; and
where the electrical line is a lightning rod of a rotor blade of the wind turbine.

17. Device according to claim 16,
wherein the coupling-in module is configured to be attached to the lightning rod of a rotor blade and/or to be integrated into the lightning rod of the rotor blade; and/or
wherein the coupling-in module is configured to be attached in a feed line to the rotor blade and/or to be integrated into a feed line to the rotor blade; and/or
wherein the coupling-in module is configured to be integrated into a rotor blade and/or to be attached in a rotor blade.

18. Device according to claim 16,
wherein the device comprises a plurality of coupling-in modules corresponding to the plurality of rotor blades; and
wherein a respective coupling-in module is configured to couple the electrical test signal into a respective rotor blade for continuity testing of a respective lightning rod.

19. Device according to claim 16,
wherein the device comprises a plurality of coupling-in modules corresponding to the plurality of rotor blades;
wherein a respective coupling-in module is configured to couple a respective electrical test signal into a respective rotor blade for continuity testing of a respective lightning rod; and
wherein the device comprises a plurality of signal generators corresponding to the plurality of coupling-in modules, and wherein a respective signal generator of the plurality of signal generators is configured to generate the respective electrical test signal for coupling the same into a respective lightning rod in the active operating mode.

20. Device according to claim 19,
wherein the energy source is configured to supply the plurality of signal generators with energy; or
wherein the device comprises a plurality of energy sources corresponding to the plurality of signal generators, and wherein a respective energy source of the plurality of energy sources is configured to supply a respective signal generator of the plurality of signal generators with energy.

21. System for providing electrical test signals, for performing a continuity test of electrical lines of an object, wherein the object is a wind turbine with a plurality of rotor blades, the rotor blades each comprising electrical lines in the form of lightning rods, and wherein the system further comprises:
a plurality of devices according to claim 1, wherein a respective coupling-in module of a respective device is configured to couple a respective electrical test signal into a respective rotor blade for continuity testing of a respective lightning rod.

22. System for providing an electrical test signal, for performing a continuity test of an electrical line of an object, comprising:
a device according to claim 1;
a communication unit configured to:
transmit the activation signal and the deactivation signal to the communication module of the device; and
a measuring unit configured to detect the test signal.

23. System according to claim 22, wherein the communication unit is configured to be attached to a drone.

24. System according to claim 22, wherein the measuring unit is configured to:
be attached to a drone; and
detect the test signal during an inspection flight of the drone along the object.

25. System according to any of claim 21, wherein the object is a wind turbine with a plurality of rotor blades, wherein the rotor blades each comprise electrical conductors in the form of lightning rods, and wherein the system further comprises:
a plurality of devices according to claim 1, wherein a respective coupling-in module of a respective device is configured to couple a respective electrical test signal into a respective rotor blade for continuity testing of a respective lightning rod; and
wherein the communication unit is configured to transmit the activation signal and the deactivation signal to a respective communication module of a respective device; and
wherein a drone comprises the measuring unit and wherein the drone is configured to fly to the wind turbine and to fly along the plurality of rotor blades.

26. System according to claim 22, wherein the object is a wind turbine with a plurality of rotor blades, wherein the rotor blades each comprise electrical conductors in the form of lightning rods, and wherein the system further comprises:
a plurality of devices according to any of claim 1, wherein a respective coupling-in module of a respective device is configured to couple a respective electrical test signal into a respective rotor blade for continuity testing of a respective lightning rod; and
wherein the communication unit is configured to transmit the activation signal and the deactivation signal to a respective communication module of a respective device; and
wherein a drone comprises the measuring unit and wherein the drone is configured to fly to the wind turbine and to fly along the plurality of rotor blades.

27. System according to claim 22, wherein the measuring unit is a portable device.

28. Method of performing a continuity test of an electrical line of an object, comprising:
supplying a communication module with energy of an energy source; and
acquiring an activation signal by means of the communication module to switch from a passive operating mode to an active operating mode; and
supplying a signal generator with energy of the energy source in the active operating mode; and
generating an electrical test signal by means of the signal generator in the active operating mode; and
coupling the electrical test signal into the electrical line of the object in the active operating mode; and
acquiring a deactivation signal by means of the communication module to switch from active operating mode to passive operating mode.

29. Method according to claim 28, further comprising:
transmitting the activation signal to the communication module by means of a communication unit;
scanning the object with a measuring unit;
detecting the test signal when scanning the object;
transmitting the deactivation signal to the communication module by means of the communication unit.

30. Method according to claim 28, further comprising:
flying to the object with a drone, wherein the drone has a measuring unit;
transmitting the activation signal to the communication module by means of a communication unit;
flying along the object with the drone;
detecting the test signal by means of the measuring unit when flying along the object;
transmitting the deactivation signal to the communication module by means of the communication unit.

31. Method according to claim 30, further comprising:
activating the communication module in the passive operating mode at timed intervals for a predetermined duration to receive the activation signal; and
transmitting the activation signal by means of the communication unit to the communication module during a time span greater than a time interval between two activations of the communication module; and
acquiring the activation signal by means of the communication module to switch from the passive operating mode to the active operating mode; and
transmitting information about the operating status to the communication unit by means of the communication module.

32. Method according to one of claim 30, wherein, for each detected value of the test signal, at least one of a time information, an absolute position information of the drone and/or a distance information and/or a position information of the drone with respect to the rotor blade is stored together with the detected value of the test signal.

33. Method according to claim 29, further comprising:
comparing the detected test signal with a reference signal, wherein the reference signal is:
a calculated signal curve of a detected test signal across the electrical line, and/or
a signal curve of the detected test signal across the electrical line measured during a previous measurement,
that is used to determine information about damage to the electrical cable.

34. Method according to claim 28,
wherein the object is a wind turbine with a rotor hub and a plurality of rotor blades arranged on the rotor hub, and wherein the rotor blades each comprise electrical lines in the form of lightning rods; and
wherein devices of a plurality of devices according to claim 1 are each coupled to a lightning rod of a respective rotor blade; and
wherein the method further comprises:
approaching the wind turbine by means of a drone, wherein the devices are in the passive operating mode when the drone approaches;
transmitting an activation signal to a communication module of one of the devices by means of a communication unit of the drone to set the one device in the active operating mode;
coupling, by means of the coupling-in module of the one device, a test signal generated by the signal generator of the one device into the lightning rod of the rotor blade coupled to the one device;
flying along the rotor blade, coupled to the one device, with the drone while the test signal is coupled into the lightning rod of the rotor blade;
detecting the test signal by means of a measuring unit of the drone during the flight along the rotor blade;
transmitting a deactivation signal, by means of the communication unit of the drone, to the communication module of the one device to set the one device back into the passive operating mode; and
iteratively repeating transmitting an activation signal, coupling in a test signal, flying along the rotor blade, detecting the test signal, and transmitting a deactivation signal for the further devices and the further rotor blades, coupled to the devices, of the plurality of devices.
